(19) United States
(12) Patent Application Publication
(10) Pub. No.: US 2008/0061331 A1
(43) Pub. Date: Mar. 13, 2008

(54) Semiconductor device and manufacturing method thereof

(75) Inventors: Wensheng Wang, Kawasaki (JP); Masaki Kurasawa, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/657,461

(22) Filed: Jan. 25, 2007

(30) Foreign Application Priority Data
Sep. 12, 2006 (JP) 2006-247089

(51) Int. Cl. H01L 29/94

(52) U.S. Cl. 257/295

(57) ABSTRACT

An impurity-doped PZT film in an amorphous state doped with La, Ca, Sr, Si, Nb and/or the like is formed on a Pt film composing a bottom electrode film. Next, crystallization annealing for the impurity-doped PZT film is performed. Next, a PZT film is formed on the impurity-doped PZT film by an MOCVD method. Thereafter, an IrO_{X} film, an IrO_{Y} film and an Ir film are formed on the PZT film.

### CROSS-REFERENCE TO RELATED APPLICATIONS

This application is based upon and claims the benefit of priority from the prior Japanese Patent Application No. 2006-247089, filed on Sep. 12, 2006, the entire contents of which are incorporated herein by reference.

### BACKGROUND OF THE INVENTION

1. Field of the Invention

The present invention relates to a semiconductor device preferable for a ferroelectric memory, and a manufacturing method thereof.

2. Description of the Related Art

In recent years, with development of the digital technology, there has been a growing trend to process or store a large capacity of data at a high speed. Therefore, high integration density and high performance of the semiconductor devices used for electronic equipment are required.

Thus, concerning a semiconductor memory device, in order to realize, for example, high integration density of DRAM, the technique using a ferroelectric material or a high dielectric constant material in place of the conventional silicon oxide or silicon nitride as a capacity insulating film of a capacitor element composing DRAM starts to be researched and developed on a wide scale.

In order to realize a nonvolatile RAM capable of write operation and read operation at a lower voltage and a higher speed, the technique of using a ferroelectric film having spontaneous polarization characteristics as a capacity insulating film has been increasingly researched and developed. Such a semiconductor memory device is called a ferroelectric memory (FeRAM).

A ferroelectric memory stores information by using a hysteresis characteristic of a ferroelectric. The ferroelectric memory includes a ferroelectric capacitor, and the ferroelectric capacitor is constructed by sandwiching a ferroelectric film as a capacitor dielectric film between a pair of electrodes. The ferroelectric film causes polarization in accordance with an applied voltage between the electrodes, and has spontaneous polarization even after the applied voltage is removed. If the polarity of the applied voltage is inversed, the polarity of the spontaneous polarization is inversed. Accordingly, if the spontaneous polarization is detected, information can be read. The ferroelectric memory operates at a lower voltage as compared with a flash memory, and is capable of writing at a high speed with power-saving. Now, use of a logic-mounted chip (SoC: System on Chip) including a ferroelectric memory for an IC card or the like is studied.

As a ferroelectric film, a film of a PZT material, a film of a Bi-layer structure compound and the like are used. As the PZT material, lead zirconate titanate (PZT) itself, a PZT film doped with La, Ca, Sr and/or Si, and the like are cited. As the Bi-layer structure compound, SrBi₂Ta₂O₉ (SBT, Y1), and SrBi₂(Ta,Nb)₂O₉ (SBTN, YZ), and the like are cited. The ferroelectric film is formed in an amorphous state or a microcrystal state on the bottom electrode film by a sol-gel method, a sputtering method or the like, and thereafter, is crystallized by heat treatment. It is sometimes formed in a crystallized state on a bottom electrode by an MOCVD (Metal Organic Chemical Vapor Deposition) method.

The research into performing the write operation and read operation of a ferroelectric capacitor at a high speed at a low voltage is being conducted. For example, in order to enhance a fatigue endurance characteristic and retention, a research on doping PZT with a very small amount of La or Nb is conducted (Appl. Phys. Lett., Vol. 77, No. 19, P.3036 (2000), Jpn. J. Appl. Phys., Vol. 32, No. 9B, P.4168 (1993), Jpn. J. Appl. Phys., Vol. 33, No. 9B, P. 5211 (1994)). These documents describe that by doping of La or Nb, a coercitive voltage reduces and a low voltage operation is made possible, and the fatigue endurance characteristic and imprint characteristic are enhanced. Further, the specifications of U.S. Pat. No. 6,287,637 and U.S. Pat. No. 6,617,626 disclose doping a ferroelectric film PZT with Ca, Sr or La.

Generally, by doping a ferroelectric material with La or Nb, a leak current of a ferroelectric capacitor can be reduced, and the fatigue endurance characteristic can be enhanced. By doping it with Ca, a sufficient amount of polarization can be obtained even at a low applied voltage. By doping it with Sr, the retention characteristic can be enhanced. However, excessive doping of these elements reduces a switching charge amount.

In order to fabricate a ferroelectric memory with good electric characteristics and high product yield, it is important to enhance orientation of crystal which constitutes a ferroelectric film. Japanese Patent Application Laid-open No. 2003-218325 discloses that in order to obtain a ferroelectric film with high orientation of crystal, a PZT film is formed on a bottom electrode composed of Ir by a sputtering method, and thereafter, another PZT film is further formed by a MOCVD method. When the PZT film is formed by the MOCVD method, a large switching charge amount can be obtained.

However, according to this technique, the desired object is achieved, but the surface of the PZT film formed by the MOCVD method is very intensely oriented in the (100) plane and the (101) plane, and orientation in the (111) plane is weak. This can be understood from FIG. 11 of Japanese Patent Application Laid-open No. 2003-218325. Therefore, the electric characteristics cannot be said to be sufficient.

Other than the above, the specification of U.S. Pat. No. 6,627,930, Japanese Patent Application Laid-open No. 2001-28426, Japanese Patent Application No. 8-273436, Japanese Patent Application No. 2000-31407, Japanese Patent application No. 2002-151656, Japanese Patent Application Laid-open No. 2002-368200, and Japanese Patent Application Laid-open No. 2003-46064 disclose the arts relating to the method for forming a ferroelectric film, but the art which is capable of obtaining sufficient orientation has not been established so far.

### SUMMARY OF THE INVENTION

The present invention has an object to provide a semiconductor device capable of controlling orientation of a ferroelectric film in a favorable orientation, and a manufacturing method thereof.

Conventionally, when a ferroelectric film such as a PZT film is formed by an MOCVD method, a bottom electrode film is formed, and thereafter, it is raised in temperature in an MOCVD chamber under an argon atmosphere. In contrast to this method, if only the orientation of the PZT film is to be controlled, it is suitable to change the rise in temperature under the argon atmosphere to a rise in temperature under an oxygen atmosphere. However, if the temperature is raised under an oxygen atmosphere, orientation of the surface of the PZT film in the (111) plane significantly varies, and the surface easily becomes rough. Especially in the peripheral portion of the semiconductor substrate, very large protruded portions tend to occur, and surface roughness tends to occur. The reason of this is considered to be that the forefront surface of the bottom electrode film, for example, the surface of an Ir film is abnormally oxidized when the temperature rises. When Ir is abnormally oxidized, IrO_{X} is generated, and THF (Tetra Hydro Furan: C₄H₈O) or butyl acetate being a solvent of MOCVD reduces IrO_{X}. Then, a hetero-phase is generated on the occasion of reduction, and the crystallinity of the PZT film which is formed immediately thereafter degrades. If surface roughness occurs, there also arises the problem of increase in a leak current. When the PZT film is formed on the bottom electrode, sufficient orientation cannot be obtained in many cases.

Thus, as a result of repeating earnest study to solve these problems, the inventors of the present application have reached the modes of the invention which are shown as follows.

In a semiconductor device according to the invention of the present application, a bottom electrode formed above a substrate, and an impurity-doped ferroelectric film formed on the bottom electrode are provided. The impurity-doped ferroelectric film is composed of crystal of an ABO₃ type structure, and is doped with an impurity. Further, a ferroelectric film formed on the impurity-doped ferroelectric film, and a top electrode formed on the ferroelectric film are provided.

In a method for manufacturing a semiconductor device according to the invention of the present application, a bottom electrode is formed above a substrate, and then, an impurity-doped ferroelectric film is formed on the bottom electrode. The impurity-doped ferroelectric film is composed of crystal of an ABO₃ type structure, and is doped with an impurity. Next, annealing is performed for the impurity-doped ferroelectric film. Thereafter, a ferroelectric film is formed on the impurity-doped ferroelectric film. Then, a top electrode is formed on the ferroelectric film.

### BRIEF DESCRIPTION OF THE DRAWINGS

FIGS. 1A to 1Q are sectional views showing a manufacturing method of a ferroelectric memory according to a first embodiment of the present invention in sequence of process steps;

FIGS. 2A to 2C are sectional views showing a manufacturing method of a ferroelectric memory according to a second embodiment of the present invention in sequence of process steps;

FIGS. 3A and 3B are sectional views showing a manufacturing method of a ferroelectric memory according to a third embodiment of the present invention in sequence of process steps;

FIGS. 4A to 4C are sectional views showing a manufacturing method of a ferroelectric memory according to a fourth embodiment of the present invention in sequence of process steps;

FIG. 5A is an SEM photograph with low magnifying power showing a surface of a PZT film (with an impurity-doped PZT film);

FIG. 5B is an SEM photograph with high magnifying power showing a surface of a PZT film (with an impurity-doped PZT film);

FIG. 6 is a microphotograph with low magnifying power showing the surface of a PZT film (without an impurity-doped PZT film);

FIG. 7A is a graph showing repeatability of integrated intensity of orientation of the PZT film in a center portion of the wafer in the (111) plane;

FIG. 7B is a graph showing repeatability of integrated intensity of orientation of the PZT film in a peripheral portion of the wafer in the (111) plane;

FIG. 7C is a graph showing repeatability of the oriented ratio of the PZT film in the center portion of the wafer in the (222) plane;

FIG. 7D is a graph showing repeatability of the oriented ratio of the PZT film in the peripheral portion of the wafer in the (222) plane;

FIG. 8A is a graph showing the integrated intensity of the PZT film in the (100) plane;

FIG. 8B is a graph showing the integrated intensity of the PZT film in the (101) plane;

FIG. 8C is a graph showing the integrated intensity of the PZT film in the (111) plane;

FIG. 9A is a graph showing the relationship of the forming condition of the impurity-doped PZT film and the oriented ratio in the (222) plane;

FIG. 9B is a graph showing the relationship of the forming condition of the impurity-doped PZT film and the FWHM (full width half maximum) of the orientation in the (111) plane;

FIG. 10A is a graph showing the relationship of the thickness of the impurity-doped PZT film and the integrated intensity of the orientation in the (111) plane;

FIG. 10B is a graph showing the relationship of the thickness of the impurity-doped PZT film and the oriented ratio in the (222) plane; and

FIG. 10C is a graph showing the relationship of the thickness of the impurity-doped PZT film and the FWHM (full width half maximum) of the orientation in the (111) plane.

### DETAILED DESCRIPTION OF THE PREFERRED EMBODIMENTS

Embodiments of the present invention will now be described concretely with reference to the attached drawings. It should be noted that the sectional structure of each memory cell of a ferroelectric memory will be described with its manufacturing method here for convenience.

### First Embodiment

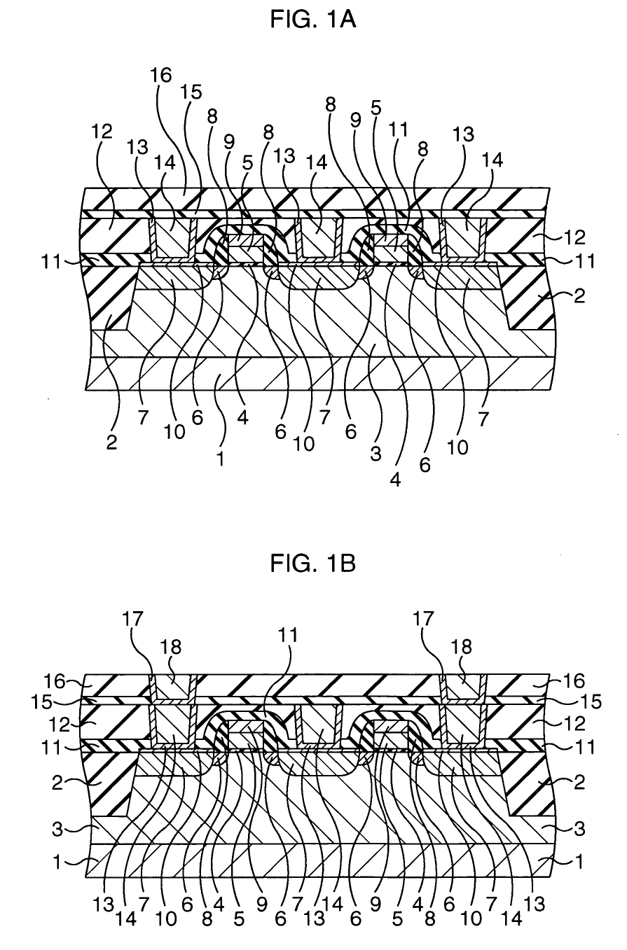

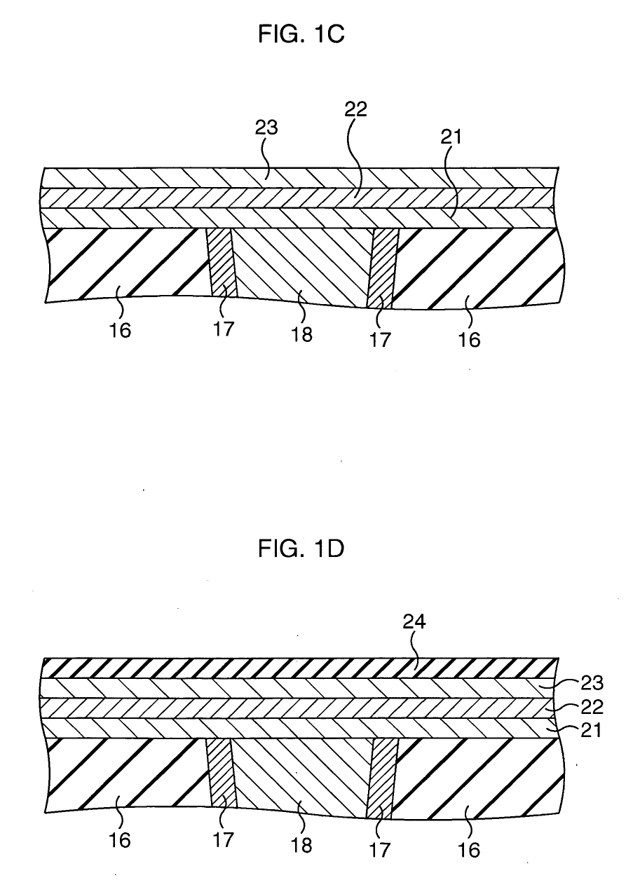

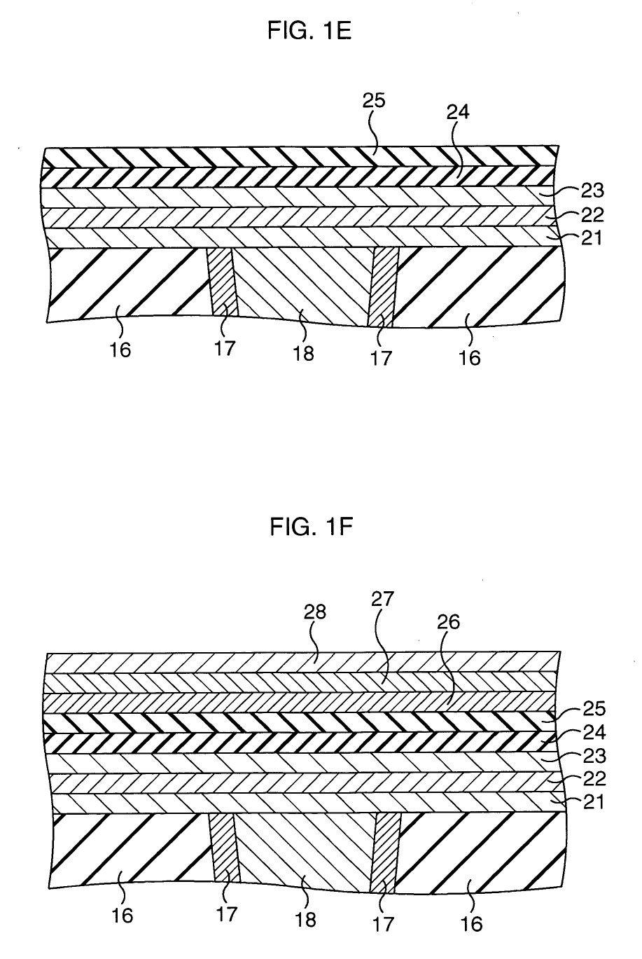

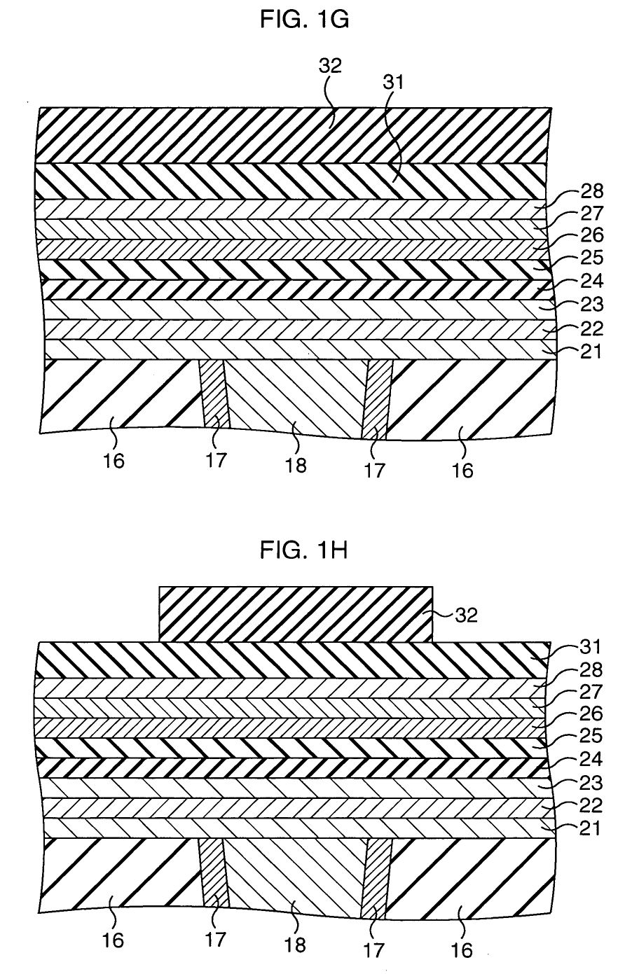

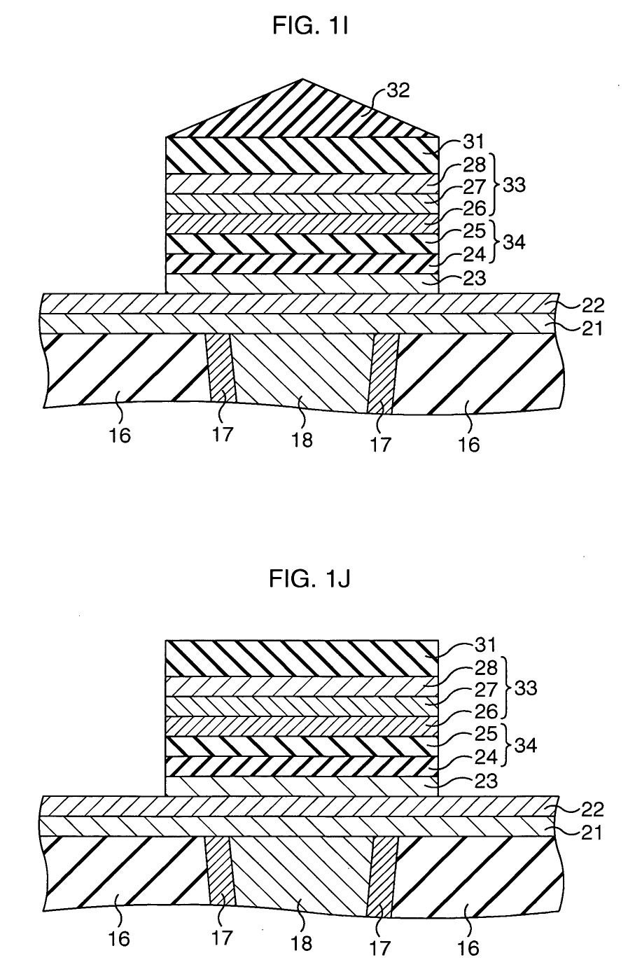

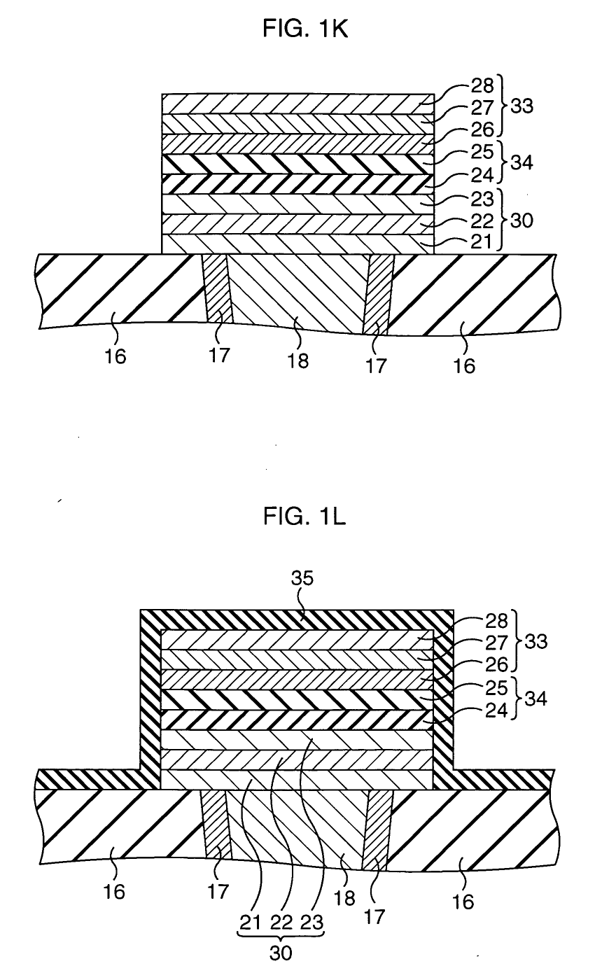

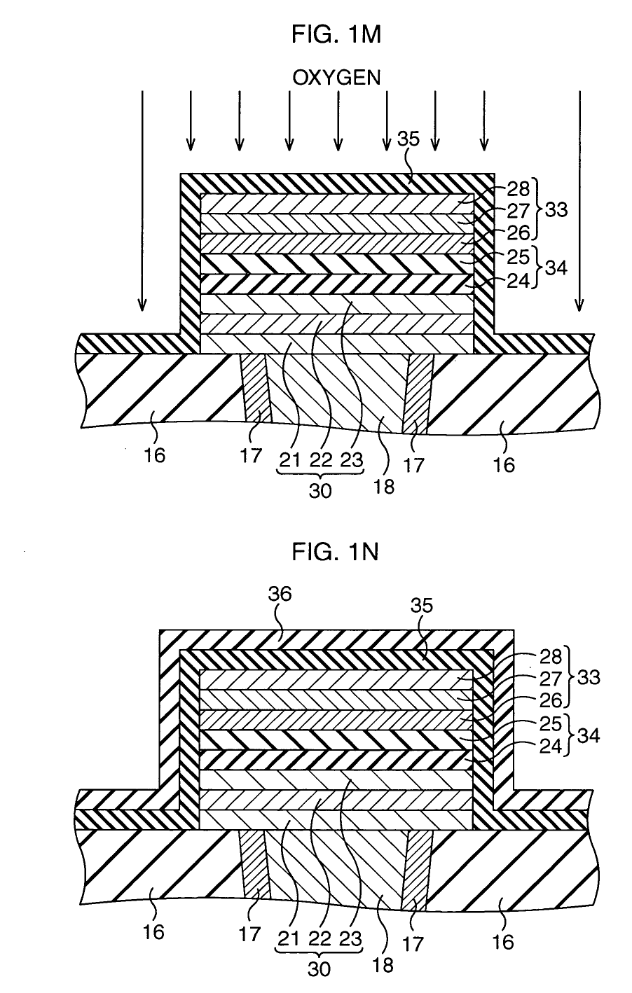

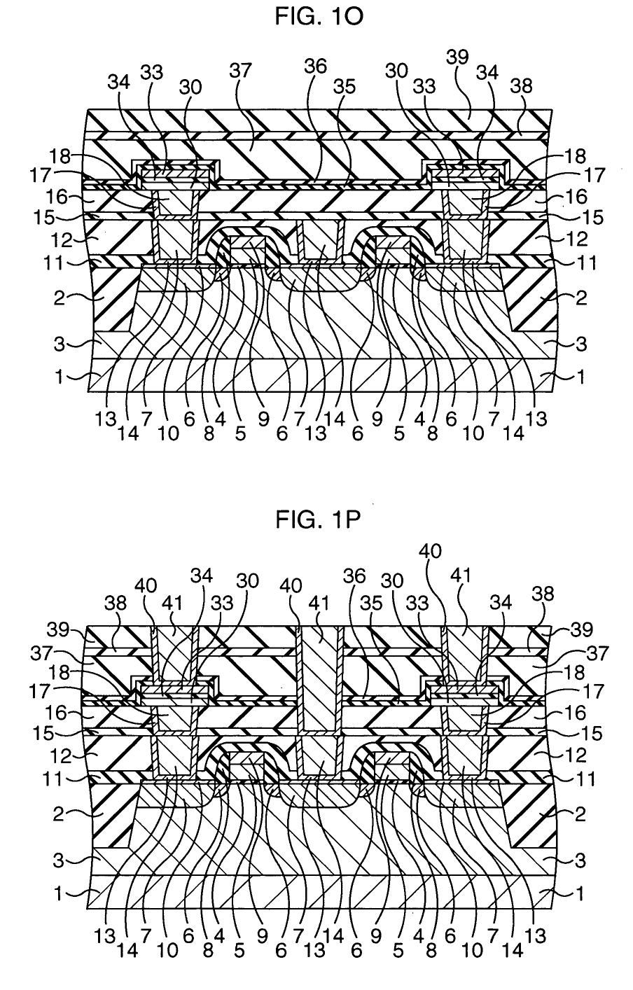

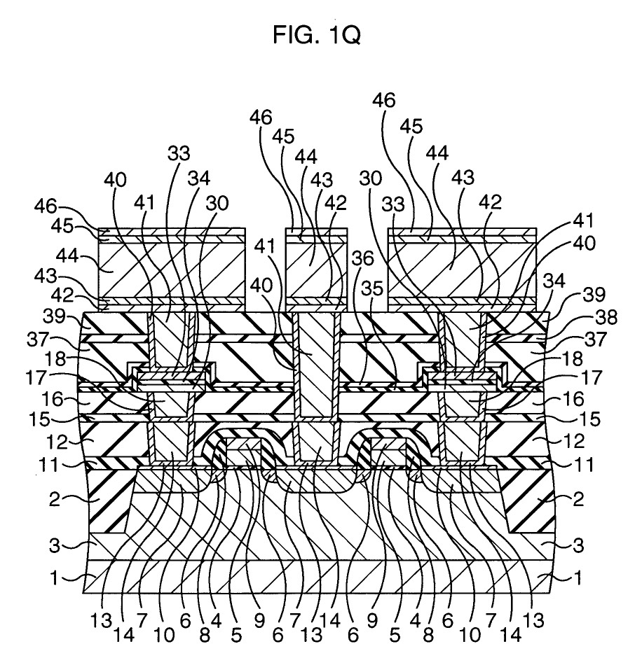

A first embodiment of the present invention will be described first. FIGS. 1A to 1Q are sectional views showing a manufacturing method of a ferroelectric memory (semiconductor device) according to the first embodiment of the present invention in sequence of the process steps.

In the first embodiment, first, as shown in FIG. 1A, a trench for STI (Shallow Trench Isolation) which defines an active region of a transistor is formed on a surface of an n-type or a p-type silicon substrate 1, and by burying an insulation film of silicon oxide or the like therein, an element isolation insulating film 2 is formed. The element isolation insulating film may be formed by an LOCOS (Local Oxidation of Silicon) method.

Next, by introducing a p-type impurity into the active region, a p-well 3 is formed. Next, by thermally oxidizing the surface of the active region, a gate insulating film 4 is formed. Subsequently, an amorphous or polycrystalline silicon film is formed on an entire surface over the silicon substrate 1, and by patterning this by a photolithography technique, a gate electrode 5 is formed. At this time, two gate electrodes 5 are disposed on the p-well 3 to be parallel with each other. These gate electrodes 5 function as part of a word line of a memory.

Next, introduction (ion implantation) of an n-type impurity is performed by using the gate electrodes 5 as a mask, and thereby, extension layers 6 are formed at both sides of the gate electrodes 5. Thereafter, an insulating film is formed on the entire surface over the silicon substrate 1, and by etching it back, insulating side walls 8 are formed at the sides of the gate electrodes 5. As the insulating film, for example, a silicon oxide film is formed by a CVD method.

Subsequently, by performing introduction (ion implantation) of an n-type impurity by using the side walls 8 and the gate electrodes 5 as a mask, impurity diffusion layers 7 are formed at both sides of the gate electrodes 5. Two sets of the extension layers 6 and the impurity diffusion layers 7 constitute a source and a drain of an MOS transistor.

Next, a refractory metal layer such as a cobalt layer is formed on the entire surface over the silicon substrate 1 by a sputtering method, and the refractory metal layer is heated to be reacted with silicon. As a result, a silicide layer 9 of a refractory metal is formed on the gate electrodes 5, and a silicide layer 10 of a refractory metal is formed on the impurity diffusion layer 7. The unreacted refractory metal layer on the element isolation insulating film 2 and the like is removed by wet etching.

Next, a silicon oxynitride film 11 of a thickness of about 200 nm is formed on the entire surface over the silicon substrate 1 by a plasma CVD method, for example. Next, a silicon oxide film 12 of a thickness of about 1000 nm is formed on the silicon oxynitride film 11 by a plasma CVD method using a TEOS gas as a source gas, for example. Thereafter, a top surface of the silicon oxide film 12 is polished and flattened by a CMP (Chemical Mechanical Polishing) method. In the flattening, the thickness of the silicon oxide film 12 is made about 700 nm from the top surface of the silicon substrate 1.

Next, by patterning the silicon oxide film 12 and the silicon oxynitride film 11 by a photolithography technique, contact holes in which the silicide layers 10 are exposed are formed. The diameter of the contact hole is made, for example, 0.25 μm. Next, by sequentially forming a Ti film of a thickness of about 30 nm and a TiN film of a thickness of about 20 nm on the bottom portions and side portions of the contact holes, a glue film (adhesive film) 13 is formed. Thereafter, a tungsten film (W film) 14 is formed in the contact holes and on the silicon oxide film 12. The thickness of the W film 14 is made about 300 nm from the top surface of the silicon oxide film 12. Subsequently, by performing CMP, the glue film 13 and the W film 14 are left only in the contact holes. Contact plugs are constituted of them. In the CMP, by performing over polishing, the glue films 13 and the W film 14 on the silicon oxide film 12 are completely removed.

Next, a silicon oxynitride film 15 of a thickness of about 130 nm is formed on the silicon oxide film 12 and the contact plugs as an oxidation prevention film by a plasma CVD method, for example. Further, on the silicon oxynitride film 15, a silicon oxide film 16 of a thickness of about 300 nm is formed by a plasma CVD method using a TEOS gas as a source gas, for example. As the oxidation preventing film, instead of the silicon oxynitride film 15, a silicon nitride film or an aluminum oxide film may be formed.

Next, as shown in FIG. 1B, by patterning the silicon oxide film 16 and the silicon oxynitride film 15 by a photolithography technique, contact holes in which the silicide layers 10 are exposed are formed. The diameter of the contact hole is, for example, 0.25 μm. Next, a Ti film of a thickness of about 30 nm and a TiN film of a thickness of about 20 nm are sequentially formed on the bottom portions and side portions of the contact holes, and thereby, a glue film (adhesive film) 17 is formed. Thereafter, tungsten films (W films) 18 are formed in the contact holes and on the silicon oxide film 16. The thickness of the W film 18 is about 300 nm from the top surface of the silicon oxide film 16. Subsequently, by performing CMP, the glue films 17 and the W films 18 are left in only the contact holes. Contact plugs are constituted of them. In the CMP, by performing over polishing, the glue film 17 and the W film 18 on the silicon oxide film 16 are completely removed.

Next, by performing NH₃ plasma processing for the surface of the silicon oxide film 16, NH groups are bonded to oxygen atoms on the surface of the silicon oxide film 16. In this plasma processing, for example, a parallel plate type plasma processing apparatus provided with opposed electrodes at a position separated by about 9 mm (350 mils) from the silicon substrate 1 is used. In the state in which the set temperature of the silicon substrate 1 is made 400° C., and the pressure in the chamber is set at 266 Pa (2 Torr), an ammonia gas is supplied into the chamber at a flow rate of 350 sccm. A radiofrequency of 13.56 MHz is supplied to the silicon substrate 1 side with power of 100 W, and a radiofrequency of 350 kHz is supplied to the opposed electrodes with power of 55 W. These are continued for 60 seconds.

Next, a Ti film of a thickness of about 20 nm is formed on the silicon oxide film 16 and the contact plugs. In formation of the Ti film, for example, a sputtering apparatus provided with a target at the position separated by about 60 mm from the silicon substrate 1 is used. Then, in the state in which the set temperature of the silicon substrate 1 is made 20° C., the pressure in the chamber is set at 0.15 Pa, and the atmosphere in the chamber is made an Ar atmosphere, sputtering DC power of 2.6 kW is supplied for five seconds. In this embodiment, before formation of the Ti film, NH₃ plasma processing has been performed for the surface of the silicon oxide film 16. Therefore, Ti atoms deposited thereon are not captured by oxygen atoms, and can freely move on the surface of the silicon oxide film 16. As a result, the Ti film is self-organized, and its surface intensely orients in the (002) plane. Thereafter, by performing RTA (Rapid Thermal Annealing) at 650° C. for 60 seconds under a nitrogen atmosphere, the Ti film is made a TiN film 21 of which surface is intensely oriented in the (111) plane as shown in FIG. 1C.

Subsequently, a TiAlN film 22 of a thickness of about 100 nm is formed on the TiN film 21 as an oxygen diffusion barrier film by a reactive sputtering method, for example. At this time, a target made by alloying Ti and Al, for example, is used. The set temperature of the silicon substrate 1 is made 400° C., the pressure inside the chamber is set at 253.3 Pa, Ar is supplied at a flow rate of 40 sccm and N₂ is supplied at a flow rate of 10 sccm, into the chamber. The sputtering power is set at, for example, 1.0 kW.

Next, a Pt film 23 of a thickness of about 100 nm is formed on the TiAlN 22 as a noble metal film by a sputtering method, for example. At this time, the set temperature of the silicon substrate 1 is made 400° C., the pressure in the chamber is set at 0.2 Pa, and the atmosphere in the chamber is made an Ar atmosphere. The sputtering power is set at, for example, 0.5 kW. As the noble metal film, a Pd film, a Pt alloy film or a Pd alloy film may be formed instead of the Pt film 23. Instead of the Pt film 23, as an oxide conductive film with the structure of a perovskite type crystal, an SRO film (SrRuO₃ film), an LSCO film (LaSrCoO₃ film) or the like may be formed. Namely, the films having the lattice constants close to that of PZT can be used.

Next, RTA at 650° C. or higher for 60 seconds is performed under an Ar atmosphere. As a result, adhesion among the Pt film 23, the TiAlN film 22 and the TiN film 21 is enhanced, and crystallinity of the Pt film 23 is enhanced.

Next, as shown in FIG. 1D, an impurity-doped PZT film 24 in an amorphous state is formed on the Pt film 23 as an impurity-doped ferroelectric film by a sputtering method at a room temperature, for example. As the impurity-doped PZT film 24, a PZT film doped with La, Ca, Sr, Si, Nb and/or the like is formed. For example, a PZT film doped with 5 mol % of Ca, 2 mol % of La and 2 mol % of Sr is formed.

Any ferroelectric film can be used as an impurity-doped ferroelectric film instead of the impurity-doped PZT film 24, as long as the ferroelectric film is doped with an impurity and has the crystal structure of an ABO₃ type perovskite structure. In the ABO₃ type perovskite structure, atoms of Bi, Pb, La, Ba, Sr, Ca, Na, K, rare-earth elements and the like can be disposed in the A site. Meanwhile, atoms of Ti, Zr, Nb, Si, Ir, Ru, Ta, W, Mn, Fe, Co, Cr and the like can be disposed in the B site. A plurality of A sites exist in the perovskite structure of one unit, but the atoms disposed in the respective A sites do not have to be the same at each unit. The same thing applies to the atoms disposed in the B sites.

A ferroelectric film of an ABO₃ type Bi layer structure is also included in the ABO₃ type perovskite structure. This is because if it is seen as one unit, the ABO₃ type Bi layer structure is equivalent to the ABO₃ type perovskite structure. As the ferroelectric of the ABO₃ type Bi layer structure, (Bi₁₋ₓRₓ)Ti₃O₁₂ (R is a rare-earth element: 0<x<1), SrBi₂Ta₂O₉, SrBi₄Ti₄O₁₅ and the like are cited.

After formation of the impurity-doped PZT film 24, RTA under an atmosphere of an inert gas, or under an atmosphere including an oxidizing gas and an inert gas is performed for the impurity-doped PZT film 24. For example, the heat treatment temperature is set at 500° C. or higher (for example, 580° C.), the heat treatment time is set at 30 seconds to 120 seconds (for example, 90 seconds), the flow rate of O₂ is set at 25 sccm or less, and the flow rate of Ar is set at 2000 sccm. As a result, the impurity-doped PZT film 24 is crystallized. The heat treatment temperature may differ in accordance with the material of the impurity-doped PZT film 24, and, for example, 600° C. or lower is preferable in the case of a PZT series material, 700° C. or lower is preferable in the case of a BLT series material, and 800° C. or lower is preferable in the case of an SBT series material.

As the inert gas, for example, an Ar gas, an N₂ gas and/or a He gas can be used. As the oxidizing gas, an O₂ gas, an O₃ gas and/or an N₂O gas can be used. As will be described later, the flow rate of the oxidizing gas is preferably set at 25 sccm or less, especially preferably at 10 sccm or less.

Next, as shown in FIG. 1E, a PZT film 25 of a thickness of about 80 nm is formed on the impurity-doped PZT film 24 by an MOCVD method, for example. At this time, as a raw material of Pb, Pb(C₁₁H₁₉O₂)₂ is used. Pb(C₁₁H₁₉O₂)₂ is sometimes expressed as Pb(DPM)₂. As a raw material of Zr, Zr(C₉H₁₅O₂)₄ is used. Zr(C₉H₁₅O₂)₄ is sometimes expressed as Zr(DMHD)₄. As a raw material of Ti, Ti(C₃H₇O)₂(C₁₁H₁₉O₂)₂ is used. Ti(C₃H₇O)₂(C₁₁H₁₉O₂)₂ is sometimes expressed as Ti(O-iOr)₂(DPM)₂. These are dissolved into THF solvents each in concentration of 0.3 mol/liter, and three kinds of liquid raw materials are prepared. Subsequently, these liquid raw materials are supplied to the vaporizer of an MOCVD apparatus respectively at flow rates of 0.326 ml/min, 0.200 ml/min and 0.200 ml/min together with the THF solvent at a flow rate of 0.474 ml/min, and are vaporized. In this manner, the source gases of Pb, Zr and Ti are obtained.

Instead of the PZT film 25, an SrBi₂Ta₂O₉ film, a Bi₄Ti₃O₉ film, a (Bi,La)₄Ti₃O₁₂ film, a BiFeO₃ film, a BaBi₂Ta₂O₉ film or the like may be formed. For example, a film of which crystal structure is a Bi-layer structure or a perovskite structure can be formed. As such a film, films expressed by general formulae of ABO₃ of PZT doped with a very small amount of La, Ca, Sr, Si and/or the like, SBT, BLT and Bi-layer compounds can be cited in addition to a PZT film. However, it is preferable that these films are not doped with impurities. This is for securing a large switching charge amount.

Further, the pressure in the MOCVD chamber is set at 665 Pa (5 Torr), the set temperature of the silicon substrate 1 is made 620° C., and the source gases of Pb, Zr and Ti are supplied into the MOCVD chamber for 620 seconds, for example.

Next, as shown in FIG. 1F, an IrO_{X} film 26 of a thickness of 50 nm is formed on the PZT film 25 by a sputtering method, for example. As the IrO_{X} film 26, the crystallized one is formed. At this time, the set temperature of the silicon substrate 1 is made 300° C., Ar and O₂ are supplied into the chamber each at a flow rate of 100 sccm. The sputtering power is set at, for example, about 1 kW to 2 kW. Next, RTA at 725° C. for 60 seconds is performed while O₂ is supplied at a flow rate of 20 sccm, and Ar is supplied at a flow rate of 2000 scm, into the chamber, and thereby, the PZT film 25 is completely crystallized. By this RTA, the plasma damage of the IrO_{X} film 26 is recovered, and oxygen deficiencies in the impurity-doped PZT film 24 and the PZT film 25 are compensated.

Thereafter, an IrO_{Y} film 27 of a thickness of 100 nm to 300 nm is formed on the IrO_{X} film 26 by a sputtering method, for example. When the atmosphere in the chamber is made an Ar atmosphere, the pressure in the chamber is set at 0.8 Pa, and the sputtering power is set at 1.0 kW, the thickness of the IrO_{Y} film 27 becomes about 200 nm for about 79 seconds. The composition of IrO_{Y} is preferably made a composition closer to the stoichiometric composition of IrO₂ than the composition of IrO_{X} (X<Y<2). This is because by adopting such a composition, the catalytic activity to hydrogen is suppressed, the problem of the PZT film 25 being reduced by hydrogen radicals is suppressed, and hydrogen endurance of the ferroelectric capacitor is enhanced. Instead of the IrO_{X} film 26 and/or the IrO_{Y} film 27, a film formed from Ir, Ru, Rh, Re, Os or Pd, or oxide films of them may be formed. A conductive oxide such as SrRuO₃ may be formed. Further, what is made by stacking these films may be used.

Next, an Ir film 28 of a thickness of 50 nm to 100 nm is formed on the IrO_{Y} film 27 as a hydrogen barrier film and a conductivity improving film by a sputtering method, for example. At this time, the atmosphere in the chamber is made an Ar atmosphere, the pressure in the chamber is set at 1 Pa, and the sputtering power is set at 1.0 kW. Instead of the Ir film 27, a Ru film, a Rh film or a Pd film may be formed.

Thereafter, back surface cleaning is performed. Subsequently, as shown in FIG. 1G, a titanium nitride film (TiN film) 31 and a silicon oxide film 32 are sequentially formed on the Ir film 28. The TiN film 31 is formed by a sputtering method, for example. The silicon oxide film 32 is formed by a CVD method using a TEOS gas, for example.

Next, as shown in FIG. 1H, the silicon oxide film 32 is patterned into an island shape.

Next, as shown in FIG. 1I, the TiN film 31 is etched by using the silicon oxide film 32 as a mask. As a result, a hard mask composed of the island-shaped TiN film 31 and the silicon oxide film 32 is formed.

Next, by using the TiN film 31 and the silicon oxide film 32 as a mask, plasma etching using a mixture gas of HBr, O₂, Ar and C₄F₈ as an etching gas is performed for the Ir film 28, the IrO_{Y} film 27, the IrO_{X} film 26, the PZT film 25, the impurity-doped PZT film 24 and the Pt film 23. As a result, a top electrode 33 and a capacity insulating film 34 are formed.

Subsequently, as shown in FIG. 1J, the silicon oxide film 32 is removed by dry etching or wet etching.

Next, as shown in FIG. 1K, by performing dry etching by using the Ir film 28 and the like as a mask, the TiAlN film 22 and the TiN film 21 are patterned. In this embodiment, a bottom electrode 30 is composed of the Pt film 23, the TiAlN film 22 and the TiN film 21. However, only the Pt film 23 can be regarded as the bottom electrode. The bottom electrode 30 may include a conductive film (including an oxide conductive film) containing Pt, Ir, Ru, Rh, Re, Os and/or Pd.

Next, as shown in FIG. 1L, a protection film 35 which covers a ferroelectric capacitor is formed on the silicon oxide film 16. As the protection film 35, an aluminum oxide film of a thickness of about 20 nm is formed by a sputtering method, for example.

Thereafter, as shown in FIG. 1M, in order to recover the damage of the dielectric film capacitor, recovery annealing is performed under an oxygen containing atmosphere. The conditions of the recovery annealing are not especially limited, but for example, the set temperature of the silicon substrate 1 is made 550° C. to 700° C., for example. Especially when the PZT film 25 is formed as the ferroelectric film as in this embodiment, recovery annealing at 650° C. for 60 minutes is performed under an oxygen atmosphere, for example.

Thereafter, as shown in FIG. 1N, another new protection film 36 is formed on the protection film 35. As the protection film 36, an aluminum oxide film of a thickness of about 20 nm is formed by a CVD method, for example.

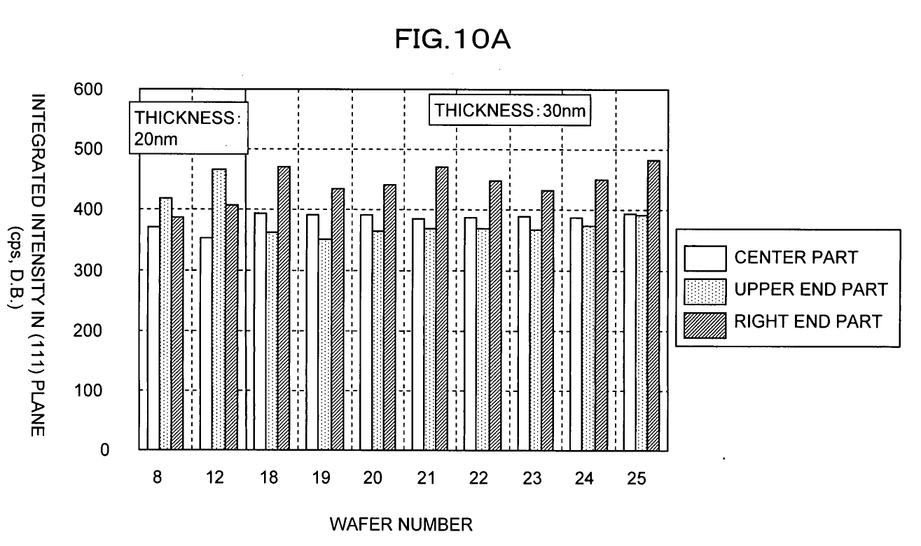

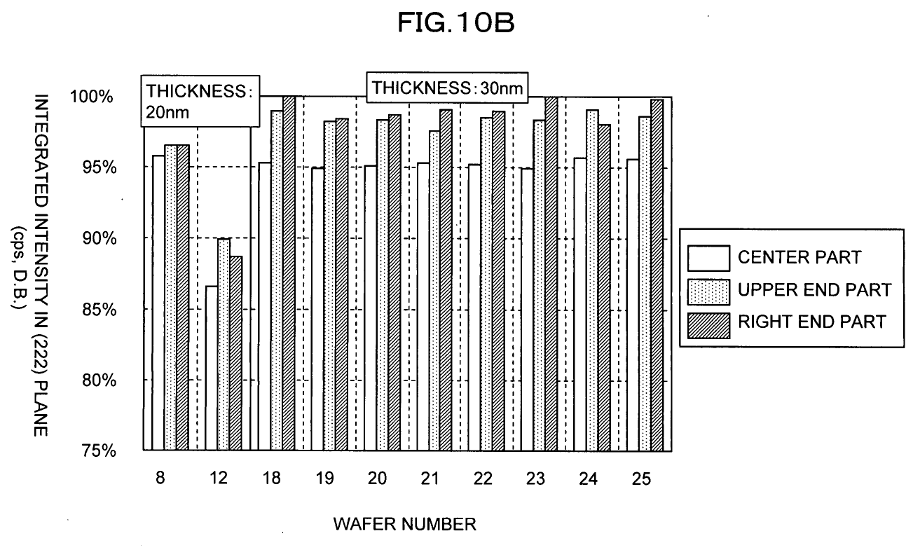

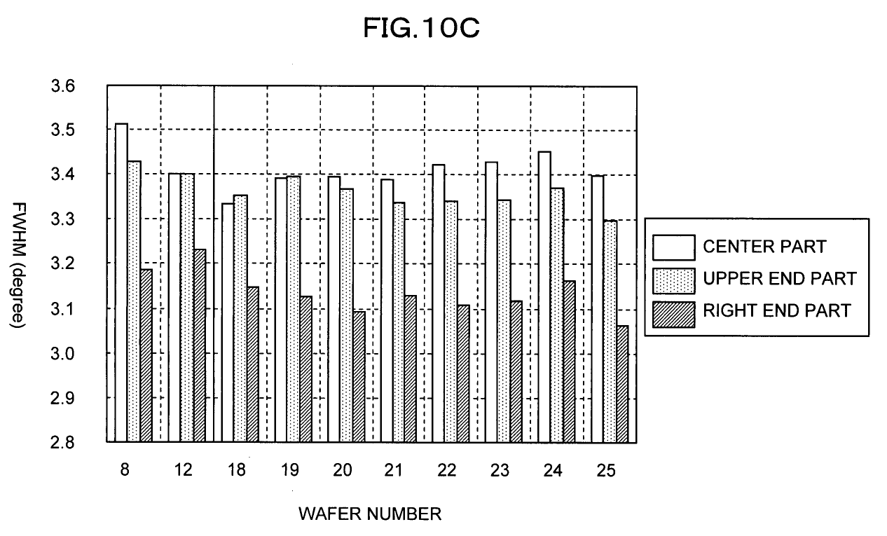

Next, as shown in FIG. 10, a silicon oxide film 37 of a thickness of about 1500 nm is formed on the protection film 36 as an interlayer insulating film by a plasma TEOSCVD method, for example. At this time, as the source gas, for example, a mixture gas composed of a TEOS gas, an oxygen gas and a helium gas is used. Thereafter, the surface of the silicon oxide film 37 is flattened by a CMP method, for example. As the interlayer insulating film, for example, an inorganic film or the like having insulation properties may be formed.

Subsequently, under a plasma atmosphere which is generated by using, an N₂O gas, an N₂ gas or the like, heat treatment is performed. As a result, moisture in the silicon oxide film 37 is removed, and the film quality of the silicon oxide film 37 is changed, whereby it becomes difficult for water to enter the silicon oxide film 37.

Thereafter, a protection film (barrier film) 38 is formed on the silicon oxide film 37 by a sputtering method or a CVD method, for example. As the protection film 38, for example, an aluminum oxide film of a thickness of 20 nm to 100 nm is formed. Since the protection film 38 is formed on the flattened silicon oxide film 37, the protection film 38 also becomes flat.

Next, a silicon oxide film 39 of a thickness of 300 nm to 500 nm is formed on the protection film 38 as an interlayer insulating film by a plasma TEOSCVD method, for example. Thereafter, the surface of the silicon oxide film 39 is flattened by a CMP method, for example. As the interlayer insulating film, a silicon oxynitride film, a silicon nitride film or the like may be formed.

Next, as shown in FIG. 1P, by patterning the silicon oxide film 39, the protection film 38 and the silicon oxide film 37 by a photolithography technique, contact holes where the top electrodes 33 are exposed are formed. By patterning the silicon oxide film 39, the protection film 38, the silicon oxide film 37, the protection film 36, the protection film 35, the silicon oxide film 16 and the silicon oxynitride film 15 by a photolithography technique, contact holes where contact plugs composed of the glue films 13 and the W films 14 are exposed are formed. The diameter of the contact holes is made, for example, 0.25 μm. Thereafter, by performing heat treatment under the oxygen atmosphere at 550° C., oxygen deficiencies which occur to the impurity-doped PZT film 24 and the PZT film 25 at the time of formation of the contact holes are recovered.

Next, by sequentially forming a Ti film of a thickness of about 30 nm and a TiN film of a thickness of about 20 nm on the bottom portions and side portions of the contact holes, a glue film (adhesive film) 40 is formed. At this time, for example, the Ti film is formed by a sputtering method, and the TiN film is formed thereon by an MOCVD method. However, when the TiN film is formed by the MOCVD method, the treatment under plasma of a mixture gas of nitrogen and hydrogen is required for removing carbon from the TiN film. In this embodiment, the forefront surface of the top electrode 33 is the Ir film 28, and therefore, even if the plasma treatment is performed, the top electrode 33 is not reduced. As the glue film 40, only the TiN film may be formed.

Thereafter, a tungsten film (W film) 41 is formed in the contact holes and on the silicon oxide film 39. The thickness of the W film 41 is set at about 300 nm from the top surface of the silicon oxide film 39. Subsequently, by performing CMP, the glue films 40 and the W film 41 are left only in the contact holes. The contact plugs are composed of them. In this CMP, by performing over polishing, the glue film 40 and the W film 41 on the silicon oxide film 39 are completely removed.

Subsequently, as shown in FIG. 1Q, wirings composed of a Ti film 42, a TiN film 43, an AlCu film 44, a TiN film 45 and a Ti film 46 are formed on the silicon oxide film 39 and the contact plugs. On formation of the wirings, the Ti film of a thickness of 60 nm, the TiN film of a thickness of 30 nm, the AlCu film of a thickness of 360 nm, the Ti film of a thickness of 5 nm, and the TiN film of a thickness of 70 nm are sequentially formed by a sputtering method, for example, and these films are patterned by using a photolithography technique.

Thereafter, formation of an interlayer insulating film, formation of a contact plug, formation of wirings of the second layer and thereafter, and the like are further performed. Then, a cover film composed of, for example, a TEOS oxide film and a SiN film is formed to complete the ferroelectric memory having a ferroelectric capacitor.

In the first embodiment as above, the impurity-doped PZT film 24 is formed at the lowermost portion of the capacitance insulating film 34. Therefore, fatigue endurance and imprint characteristics of the ferroelectric capacitor become favorable, and a low voltage operation is made possible. A leak current is decreased. Further, the PZT film 25 which is thicker than the impurity-doped PZT film 24 is formed on the impurity-doped PZT film 24, and therefore, a sufficient switching charge amount is secured. In order to secure the switching charge amount, the PZT film 25 is formed by the MOCVD method, but the impurity-doped PZT film 24 is formed at a room temperature by the sputtering method, and therefore, reaction of the impurity-doped PZT film 24 and the bottom electrode film is suppressed. In the method disclosed in Japanese Patent Application Laid-open No. 2003-218325, a ferroelectric film is formed on an Ir film by a sputtering method, but in this embodiment, the uppermost part of the bottom electrode film is the Pt film 23. Therefore, it becomes more difficult for reaction to occur.

The thickness of the impurity-doped ferroelectric film is preferably 1 nm to 50 nm, and especially preferably 20 nm to 30 nm. If it is below the lower limit, the orientation of the ferroelectric film formed thereon cannot be sometimes controlled sufficiently, and suppression of the leak current and the like may become insufficient. On the other hand, if it exceeds the upper limit, the switching charge amount may become insufficient, and the low voltage operation may become difficult.

The amount of doped substance is preferably 0.1 mol % to 5 mol % for each element. If it is below the lower limit, a sufficient effect with doping cannot be sometimes obtained. On the other hand, if it exceeds the upper limit, the switching charge amount sometimes becomes insufficient.

When a capacitor with a high dielectric constant is required instead of the ferroelectric capacitor, an impurity-doped high dielectric film and a high dielectric film are used instead of the impurity-doped ferroelectric film and the ferroelectric film. In this case, for example, a high dielectric film of oxide Zr series or oxide Pb series may be used.

### Second Embodiment

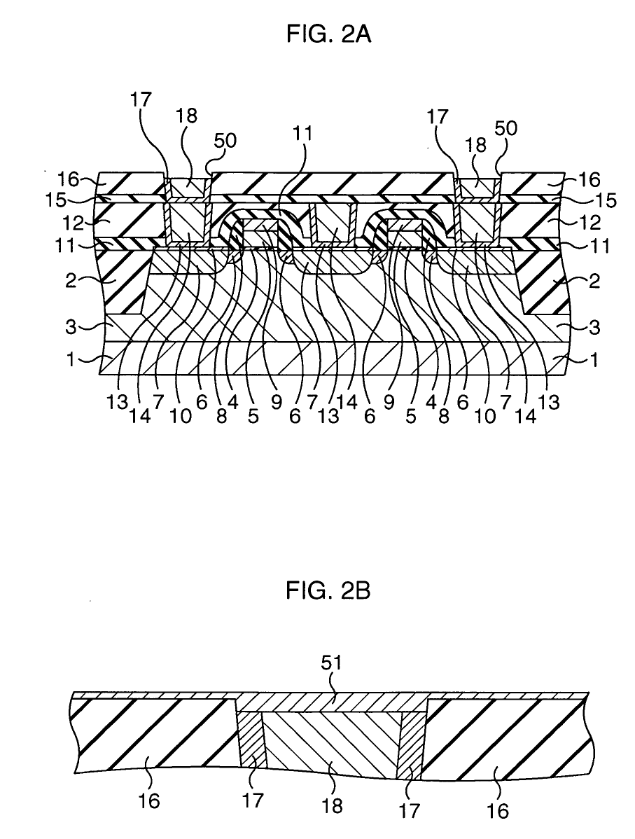

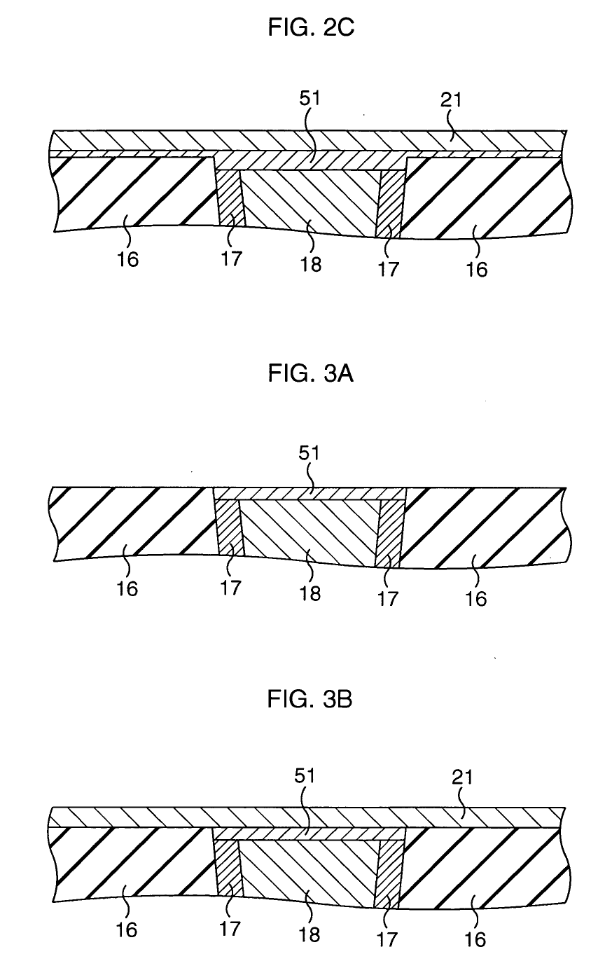

Next, a second embodiment of the present invention will be described. FIGS. 2A to 2C are sectional views showing a manufacturing method of a ferroelectric memory (semiconductor device) according to the second embodiment of the present invention in sequence of process steps.

In the second embodiment, the process up to the NH₃ plasma processing for the surface of the silicon oxide film 16 is performed first as in the first embodiment. However, on formation of the contact plugs composed of the glue film 17 and the W film 18, recesses 50 are sometimes formed on the surfaces of the contact plugs as shown in FIG. 2A. The depth of the recess 50 is, for example, about 20 nm to 50 nm.

If the same processing as in the first embodiment is performed with such recesses 50 remaining, recessed portions reflecting the recesses 50 are formed on the surface of the TiN film 21 and the like, and orientation of the impurity-doped PZT film 24 and the PZT film 25 degrades. Thus, in the second embodiment, as shown in FIG. 2B, a Ti film 51 of a thickness of about 100 nm is formed on the silicon oxide film 16 and the contact plugs. In the formation of the Ti film 51, for example, a sputtering apparatus with a target provided at the position separated by about 60 mm from the silicon substrate 1 is used. In the state in which the set temperature of the silicon substrate 1 is made 20° C., the pressure inside the chamber is set at 0.15 Pa, and the atmosphere in the chamber is made an Ar atmosphere, sputtering DC power at 2.6 kW is supplied for 35 seconds. Since in this embodiment, NH₃ plasma processing has been performed for the surface of the silicon oxide film 16 before formation of the Ti film 51, Ti atoms which are deposited thereon can freely move on the surface of the silicon oxide film 16 without being captured by oxygen atoms. As a result, the Ti film 51 is self-organized, and its surface is intensely oriented in the (002) plane.

Thereafter, the surface of the Ti film 51 is flattened by a CMP method, for example. The thickness of the Ti film 51 after being flattened is made, for example, 50 nm to 100 nm from the surface of the silicon oxide film 16. Control of the thickness is performed based on time control, for example.

Subsequently, the surface of the Ti film 51 is exposed to NH₃ plasma. Strain occurs to the crystal of the surface of the Ti film 51 due to flattening processing, and the plasma processing alleviates the strain. Therefore, degradation of the crystallinity of the film formed thereon can be prevented.

Next, a Ti film of a thickness of about 20 nm is formed on the Ti film 51. Next, as in the first embodiment, by performing RTA at 650° C. for 60 seconds under a nitrogen atmosphere, the Ti film is made the TiN film 21 with its surface intensely oriented in the (111) plane as shown in FIG. 2C.

Thereafter, processing of formation of the TiAlN film 22 and thereafter is performed as in the first embodiment.

According to the second embodiment as above, even if the recesses 50 are formed, a ferroelectric capacitor with favorable characteristics can be obtained.

### Third Embodiment

Next, a third embodiment of the present invention will be described. FIGS. 3A and 3B are sectional views of a manufacturing method of a ferroelectric memory (semiconductor device) according to the third embodiment of the present invention in sequence of process steps.

In the third embodiment, the process up to the formation of the Ti film 51 is performed first as in the second embodiment. Thereafter, as shown in FIG. 3A, the surface of the Ti film 51 is flattened until the surface of the silicon oxide film 16 is exposed by a CMP method, for example. Namely, unlike the second embodiment, the Ti film 51 on the silicon oxide film 16 is completely removed.

Subsequently, as in the second embodiment, the surface of the Ti film 51 is exposed to the NH₃ plasma. Strain occurs to crystal on the surface of the Ti film 51 due to the fattening processing, but the plasma processing alleviates the strain. Therefore, degradation in crystallinity of the film formed thereon can be prevented.

Next, a Ti film of a thickness of about 20 nm is formed on the Ti film 51. Next, as in the first and the second embodiments, by performing RTA at 650° C. under a nitrogen atmosphere for 60 seconds, the Ti film is made the TiN film 21 with its surface intensely oriented in the (111) plane as shown in FIG. 3B.

Thereafter, as in the first and the second embodiments, the process of formation of the TiAlN film 22 and thereafter is performed.

According to the third embodiment as above, the same effect as in the second embodiment is obtained.

### Fourth Embodiment

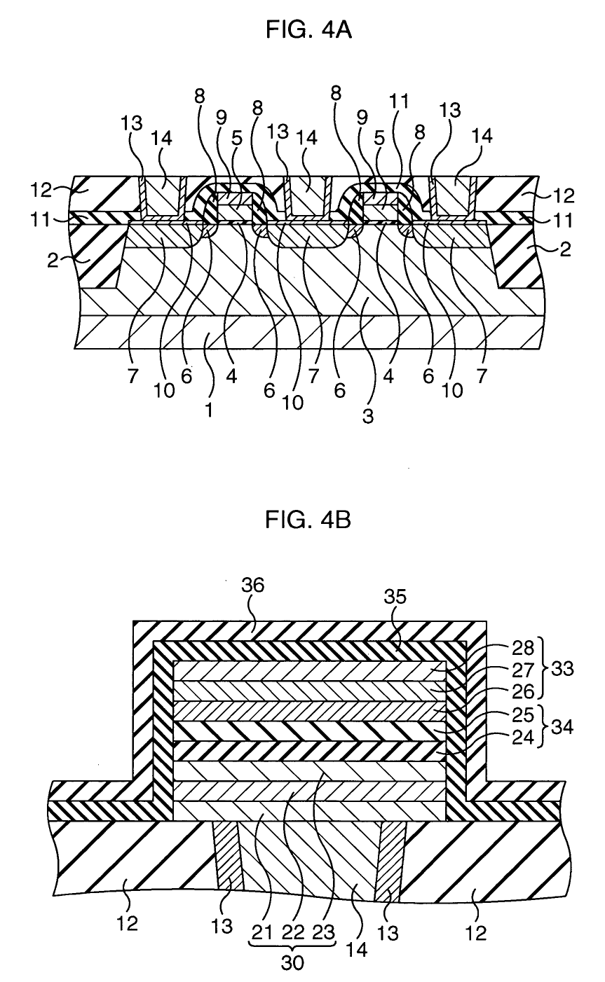

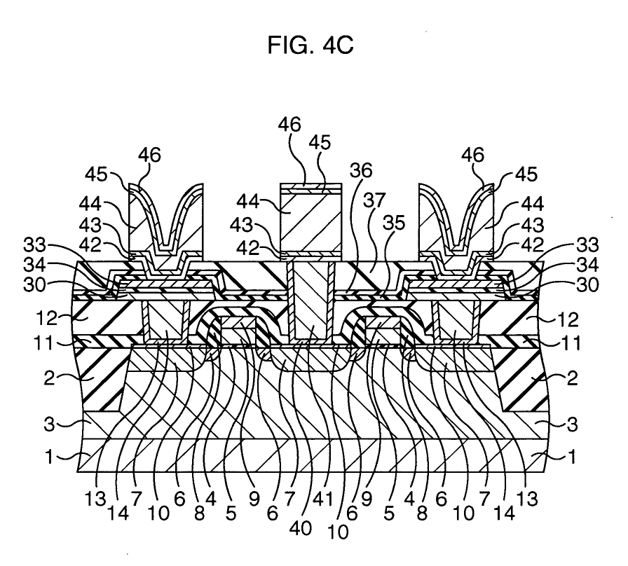

Next, the fourth embodiment of the present invention will be described. FIGS. 4A to 4C are sectional views showing a manufacturing method of a ferroelectric memory (semiconductor device) according to the fourth embodiment of the present invention in sequence of process steps.

In the fourth embodiment, the process up to the formation of the contact plugs composed of the glue film 13 and the W film 14 is performed first as in the first embodiment as shown in FIG. 4A.

Next, by performing NH₃ plasma processing for the surface of the silicon oxide film 12, NH groups are caused to bond to oxygen atoms on the surface of the silicon oxide film 12. In this plasma processing, for example, a parallel-plate type plasma processing apparatus in which opposed electrodes are provided at the position separated by about 9 mm (350 mils) from the silicon substrate 1 is used. Then, in the state in which the set temperature of the silicon substrate 1 is set at 400° C., and the pressure in the chamber is set at 266 Pa (2 Torr), an ammonia gas is supplied into the chamber at a flow rate of 350 sccm. A radiofrequency of 13.56 MHz is supplied to the silicon substrate 1 side with power of 100 W, and radiofrequency of 350 kHz is supplied to the opposed electrodes with power of 55 W. These are continued for 60 seconds.

Next, as shown in FIG. 4B, the TiN film 21 is formed on the silicon oxide film 12 and the contact plugs. The forming method of the TiN film 21 is the same as in the first embodiment. Thereafter, the process from the formation of the TiAlN film 22 to the formation of the protection film 36 is performed.

Thereafter, as shown in FIG. 4C, formation and flattening of the silicon oxide film 37 are performed similarly to the first embodiment. Next, a contact hole which reaches the silicide layer 10 shared by the two MOS transistors are formed in the silicon oxide film 37, the protection film 36, the protection film 35, the silicon oxide film 12 and the silicon oxynitride film 11. Then, in this contact hole, a contact plug composed of the glue film 40 and the W film 41 is formed. Further, with the contact plug covered with an oxidation preventing film (not shown) or the like, holes for exposing the top electrodes 33 are formed. Then, the oxidation preventing film is removed.

Subsequently, wiring and pads which are composed of the Ti film 42, the TiN film 43, the AlCu film 44, the TiN film 45 and the Ti film 46 are formed on the silicon oxide film 37, on the contact plug, and in the holes. On formation of the wiring and pads, a Ti film of a thickness of 60 nm, a TiN film of a thickness of 30 nm, an AlCu film of a thickness of 360 nm, a Ti film of a thickness of 5 nm and a TiN film of a thickness of 70 nm are formed in sequence by a sputtering method, for example, and these are patterned by using a photolithography technique.

Thereafter, formation of an interlayer insulating film, formation of a contact plug, formation of the wirings from the second layer and thereafter and the like are further performed. Then, a cover film composed of, for example, a TEOS oxide film and a SiN film is formed to complete a ferroelectric memory having a ferroelectric capacitor.

According to the fourth embodiment as above, the ferroelectric capacitor can be completed with the smaller number of process steps than in the first embodiment.

The structure of the ferroelectric capacitor may be made a planer structure instead of a stack structure.

Formation of the impurity-doped ferroelectric film is preferably performed at 500° C. or lower, and is especially preferably performed at 100° C. or lower, and as such a method, a sol-gel method is cited other than a sputtering method. As the formation method of the ferroelectric film, a sputtering method, a sol-gel method, a metallo-organic decomposition (MOD) method, a CSD (Chemical Solution Deposition) method, a chemical vapor deposition (CVD) method, an epitaxial growth method, and the like are cited in addition to an MOCVD method.

As the adhesive film, a Ti film, an Al oxide film, an Al nitride film, a TiAlN film, a Ta oxide film, a Ti oxide film, a Zr oxide film or the like may be used instead of the TiN film 21. However, in the case of using an insulating film, the structure of the ferroelectric capacitor is made a planar structure. As the oxygen barrier film, an Ir film, a Ru film or the like may be used instead of the TiAlN film 22. Instead of the Pt film 23, a Rh film, a Pd film, a Ru film or the like may be used. Instead of the IrO_{X} film 24, a Rh oxide film, a Pd oxide film, a Ru oxide film or the like may be used. As the crystallinity improving film, a Pt film, an Ir film, a Re film, a Ru film, a Pd film, an Os film or the like may be used, and oxide films of them may be used, instead of the Ti film 51.

Next, the result of the experiments conducted by the inventors of the present application will be described.

—First Experiment—

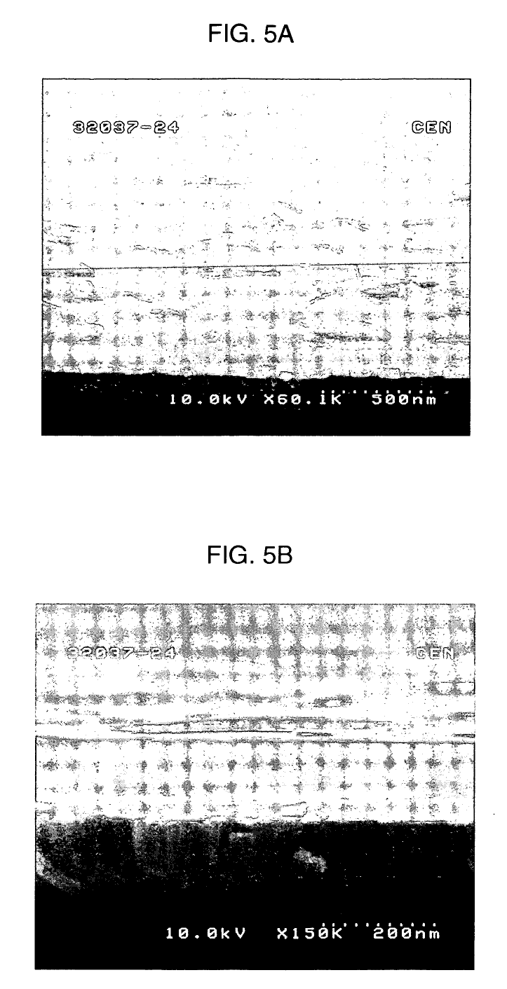

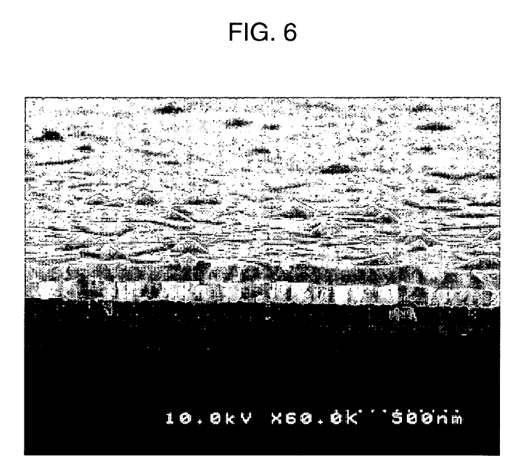

In the first experiment, the surface of the PZT film was observed. FIGS. 5A and 5B are scanning electron microscope photographs of the surface of the PZT film formed by the MOCVD method in accordance with the first embodiment. Here, FIG. 5A is the microphotograph with low magnifying power. FIG. 5B is the microphotograph with high magnifying power. FIG. 6 is a scanning electron microscope photograph of the surface of the PZT film formed on the bottom electrode by an MOCVD method, with the Ir film as the forefront surface without forming an impurity-doped PZT film. Here, the magnifying power of the SEM photograph shown in FIG. 6 is equivalent to that of the SEM photograph shown in FIG. 5A.

On the occasion of manufacturing the sample shown in FIG. 6, after the Ir film was formed, a PZT film was formed thereon by raising the temperature in the MOCVD chamber under the oxygen atmosphere. Therefore, during the temperature rise, uncontrollable abnormal oxidation occurred to the Ir film, and though it was reduced thereafter, crystallinity degraded, and irregularities occurred as shown in FIG. 6. On the other hand, in the case of following the first embodiment, irregularities did not occur as shown in FIGS. 5A and 5B. From this, it is conceivable that degradation of crystallinity hardly occurs.

—Second Experiment—

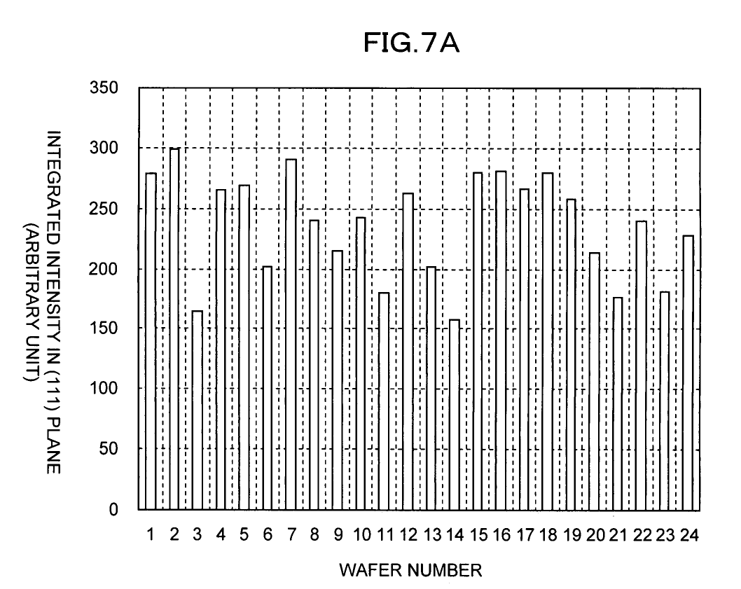

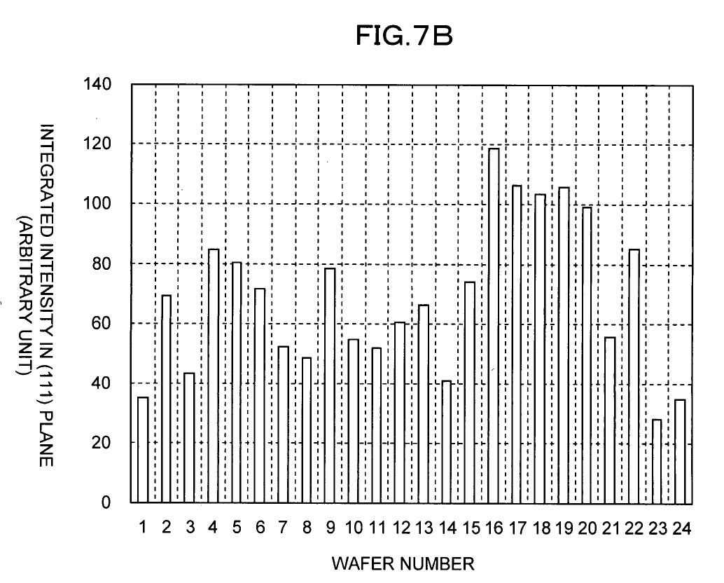

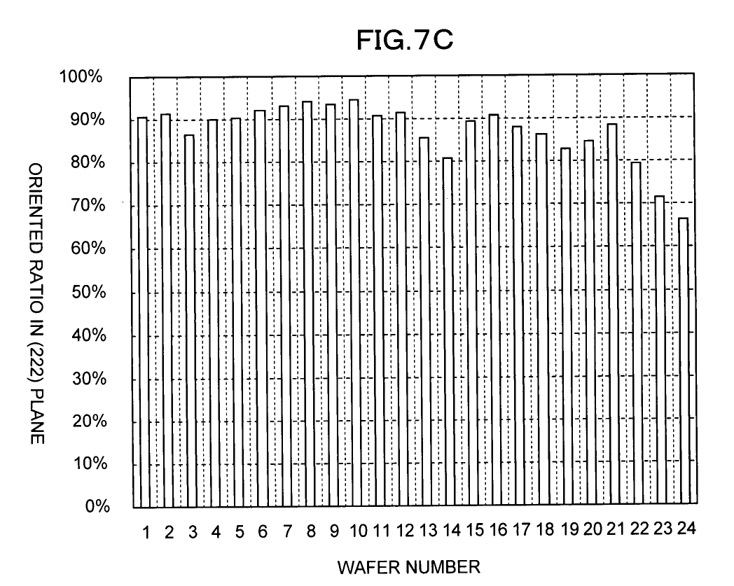

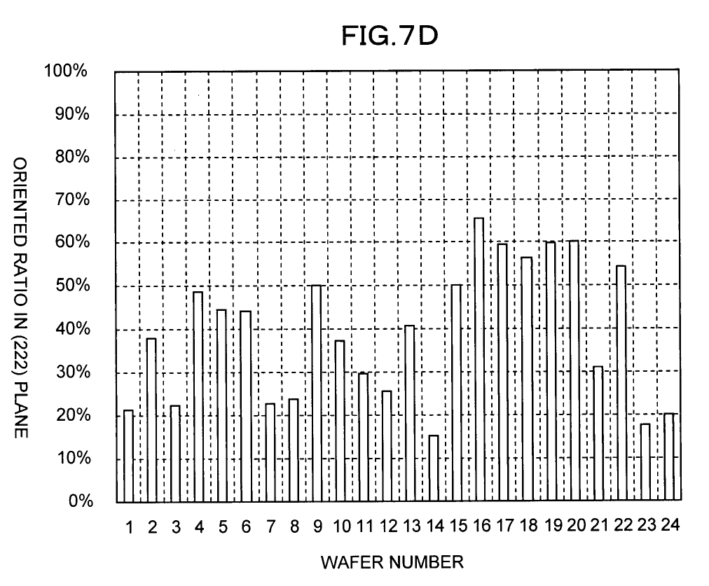

In the second experiment, repeatability of the orientation of the PZT film which was formed with the same method as the sample of which SEM photograph is shown in FIG. 6 was studied. Here, formation of the PZT film was performed for 24 wafers. The result is shown in FIGS. 7A to 7D. Here, the vertical axis of FIG. 7A represents the integrated intensity of the orientation of the PZT film in the center portion of the wafer in the (111) plane. The vertical axis of FIG. 7B represents the integrated intensity of the PZT film in the peripheral portion of the wafer in the (111) plane. FIG. 7C shows the oriented ratio of the PZT film in the center portion of the wafer in the (222) plane. FIG. 7D shows the oriented ratio of the PZT film in the peripheral portion of the wafer in the (222) plane. The oriented ratio in the (222) plane is expressed by “I₂₂₂/(I₁₀₀+I₁₀₁+I₂₂₂)” when the integrated intensity of the orientation along the (222) plane is set at I₂₂₂, the integrated intensity of the orientation along the (100) plane is set at I₁₀₀, and the integrated intensity of the orientation along the (101) plane is set at I₁₀₁.

As shown in FIG. 7A to 7D, both of the integrated intensity of the orientation along the (111) plane and the oriented ratio in the (222) plane were unstable. Especially as shown in FIGS. 7B and 7D, the variation in the peripheral portion of the wafer was large.

### Third Embodiment

In the third embodiment, the relationship between the condition (atmosphere) of RTA for the impurity-doped PZT film and crystallinity of the PZT film formed thereon by the MOCVD method was studied. In this case, as the impurity-doped PZT film, the film (CSPLZT film) of a thickness of 20 nm which was doped with the same impurity as in the first embodiment was formed by a sputtering method, and thereafter, RTA was performed under the atmosphere shown in Table 1. Subsequently, the PZT film of a thickness of 80 nm was formed thereon by a MOCVD method, and its orientation was measured. In the condition D, formation of a CSPLZT film by a sputtering method was not performed, and the PZT film of a thickness of 100 nm was formed by a MOCVD method.

TABLE 1

| | O₂ FLOW RATE | Ar FLOW RATE |
|---|---|---|
| CONDITIONS | (sccm) | (sccm) |
| A | 5 | 2000 |
| B | 5 | 10000 |
| C | 0 | 2000 |
| D | — | — |

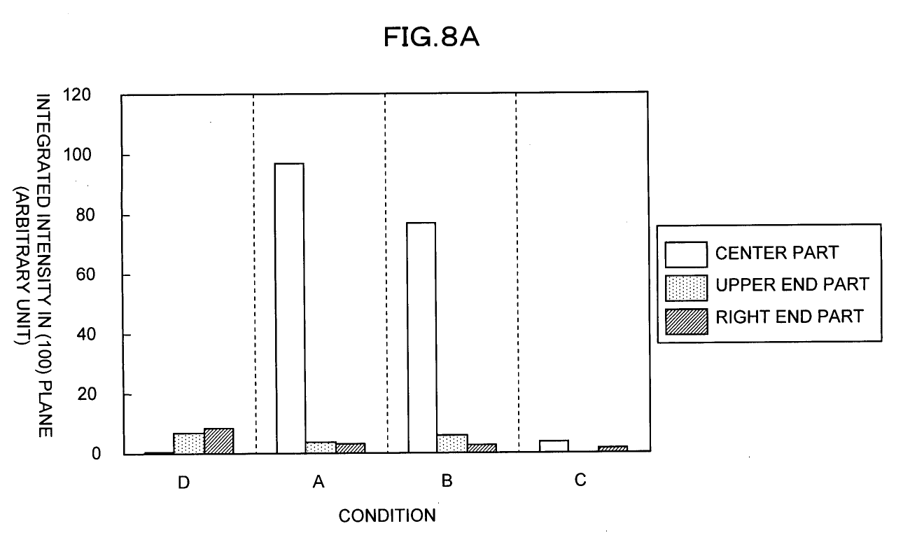

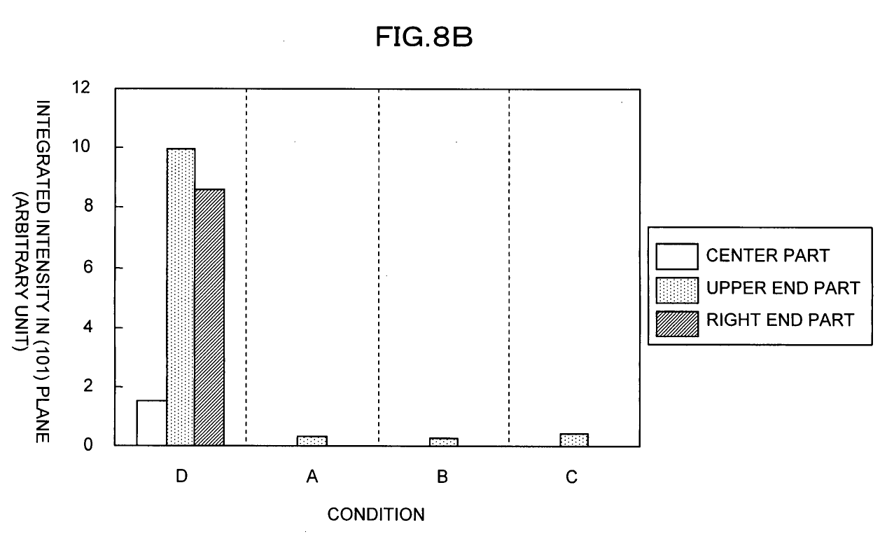

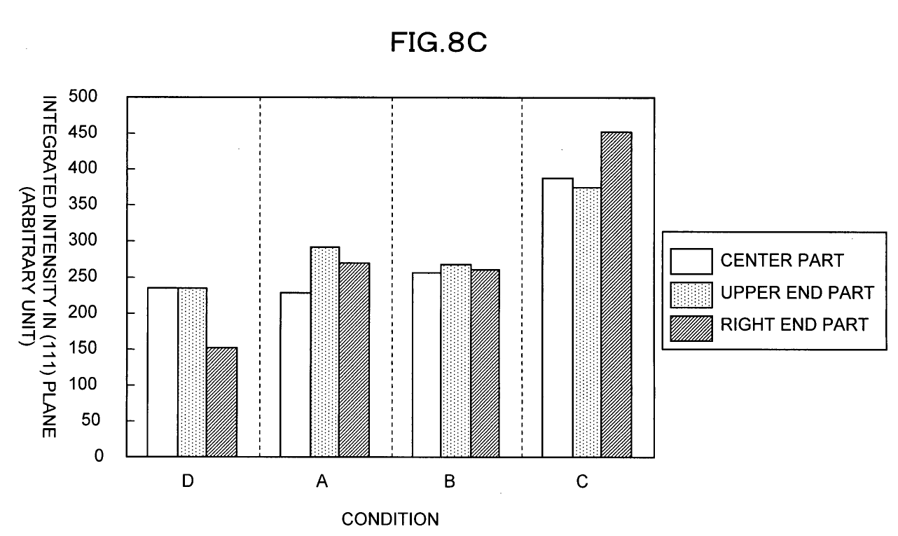

The result is shown in FIGS. 8A to 8C. FIG. 8A shows the integrated intensity of the orientation of the surface of the PZT film along the (100) plane, FIG. 8B shows the integrated intensity of the orientation along the (101) plane, and FIG. 8C shows the integrated intensity of the orientation along the (111) plane.

As shown in FIGS. 8A to 8C, the sample prepared under the condition D had the high orientation along the (101) plane. On the other hand, the samples prepared under the conditions A to C hardly had the orientation along the (101) plane. As shown in FIG. 8A, when O₂ was supplied in addition to Ar, orientation along the (100) plane increased in the center portion of the wafer. As shown in FIG. 8C, when only Ar was supplied, orientation along the (111) plane increased as a whole. Accordingly, it is considered to be preferable not to supply O₂ at all.

—Fourth Experiment—

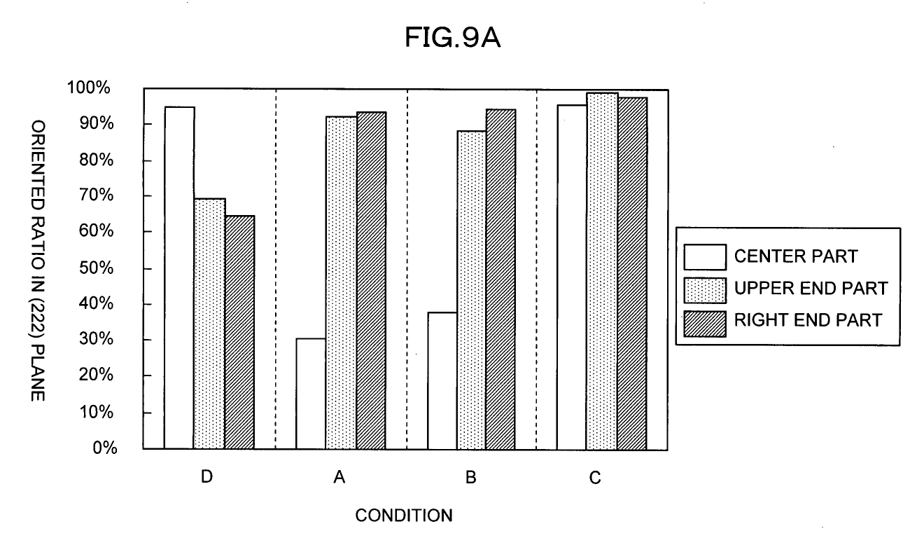

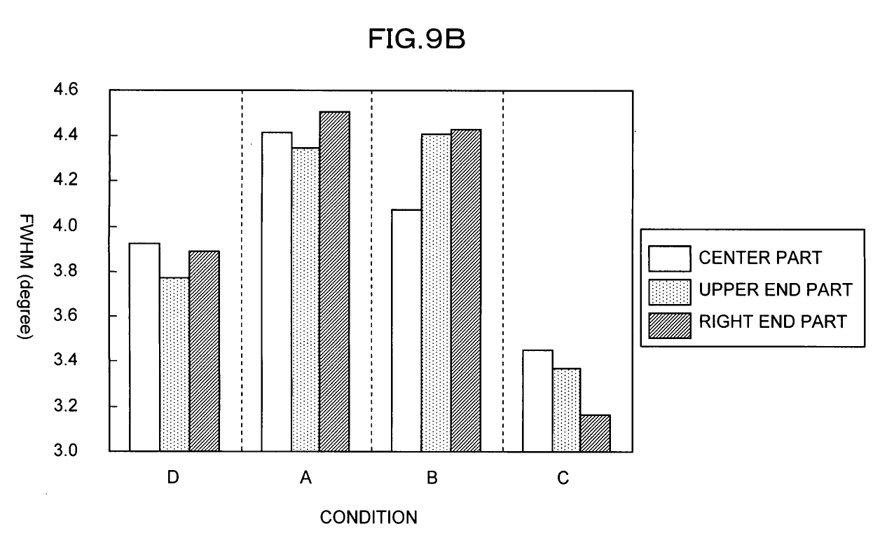

In the fourth experiment, the samples were prepared under the same four kinds of conditions as in the third experiment, and the orientations of the surface of the PZT film in them were studied. The result is shown in FIGS. 9A and 9B. FIG. 9A shows the oriented ratio in the (222) plane, and FIG. 9B shows the FWHM of the orientation along the (111) plane.

As shown in FIG. 9A, when only Ar is supplied, orientation along the (222) plane became intense, and variation was extremely suppressed. As shown in FIG. 9B, when only Ar was supplied, the FWHM was suppressed to be low. Namely, extremely favorable crystallinity was obtained. From this respect, it is considered to be favorable not to supply O₂ at all.

The favorable condition for annealing of the impurity-doped ferroelectric film which was formed by a sputtering method depends on its thickness. Thus, from the results of the third and the fourth experiments, when an oxidizing gas is supplied, it is conceivable that the flow rate is preferably set at 25 sccm or lower, and especially preferably set at 10 sccm.

—Fifth Experiment—

In the fifth experiment, repeatability of orientation of the PZT film formed following the first embodiment was studied. In this case, after the impurity-doped PZT film (CSPLZT film) of a thickness of 20 nm or 30 nm was formed by a sputtering method, it was crystallized under the Ar atmosphere. Subsequently, the PZT film was formed thereon by a MOCVD method. Then, the orientation of the surface was studied. The result is shown in FIGS. 10A to 10C. The vertical axis of FIG. 10A represents the integrated intensity of the orientation of the PZT film in the (111) plane. The vertical axis of FIG. 10B represents the oriented ratio in the (222) plane. The vertical axis in FIG. 10C represents the FWHM of the orientation along the (111) plane.

As shown in FIGS. 10A to 10C, especially when the thickness of the impurity-doped PZT film is set at 30 nm, variation reduced, and repeatability became very high. The result of other experiments show that, as the impurity-doped ferroelectric film becomes thicker, it becomes more difficult for the ferroelectric film formed thereon to orient in the (111) plane orientation, in a case that O₂ is supplied.

According to the present invention, the orientation of the ferroelectric film is made favorable, and a large switching charge amount can be obtained. Further, the effect in accordance with the kind of the impurity in the impurity-doped ferroelectric film can be obtained. For example, fatigue endurance is increased, imprint resistance is increased, and the leak current is decreased.

The present embodiments are to be considered in all respects as illustrative and no restrictive, and all changes which come within the meaning and range of equivalency of the claims are therefore intended to be embraced therein. The invention may be embodied in other specific forms without departing from the spirit or essential characteristics thereof.

What is claimed is:

1. A semiconductor device, comprising:
a bottom electrode formed above a substrate;
an impurity-doped ferroelectric film formed on said bottom electrode, said impurity-doped ferroelectric film being composed of crystal of an ABO₃ type structure, and being doped with an impurity;
a ferroelectric film formed on said impurity-doped ferroelectric film; and
a top electrode formed on said ferroelectric film.

2. The semiconductor device according to claim 1, wherein a conductive film containing Pt (platinum) or Pd (palladium) is formed on a forefront surface of said bottom electrode.

3. The semiconductor device according to claim 1, wherein an oxide conductive film composed of crystal of a perovskite structure is formed on a forefront surface of said bottom electrode.

4. The semiconductor device according to claim 1, wherein said impurity is at least one kind selected from a group consisting of La (lanthanum), Si (silicon), Sr (strontium), Ca (calcium), Ba (barium), Na (sodium), K (potassium), Nb (niobium), Ta (tantalum), W (tungsten), Mn (manganese), Fe (iron), Co (cobalt), Ir (iridium), Ru (ruthenium), Cr (chromium) and rare earth elements.

5. The semiconductor device according to claim 1, wherein said ferroelectric film is thicker than said impurity-doped ferroelectric film.

6. The semiconductor device according to claim 1, wherein a thickness of said impurity-doped ferroelectric film is 1 nm to 50 nm.

7. The semiconductor device according to claim 1, wherein said impurity-doped ferroelectric film is composed of Pb(Zr,Ti)O₃ doped with at least one kind selected from a group consisting of Sr (strontium), Ca (calcium), Nb (niobium), Ir (iridium) and La (lanthanum).

8. The semiconductor device according to claim 7, wherein a doping amount of said impurity is 5 mol % or less for each element.

9. A method for manufacturing a semiconductor device, comprising the steps of:
forming a bottom electrode above a substrate;
forming an impurity-doped ferroelectric film on said bottom electrode, said impurity-doped ferroelectric film being composed of crystal of an ABO₃ type structure, and being doped with an impurity;
performing annealing for said impurity-doped ferroelectric film;
forming a ferroelectric film on said impurity-doped ferroelectric film; and
forming a top electrode on said ferroelectric film.

10. The method for manufacturing a semiconductor device according to claim 9, wherein said impurity-doped ferroelectric film is formed at 500° C. or lower.

11. The method for manufacturing a semiconductor device according to claim 9, wherein said impurity-doped ferroelectric film is formed by a sputtering method.

12. The method for manufacturing a semiconductor device according to claim 9, wherein said step of forming a bottom electrode has the step of forming a conductive film containing Pt (platinum) or Pd (palladium) on a forefront surface of said bottom electrode.

13. The method for manufacturing a semiconductor device according to claim 9, wherein said step of forming a bottom electrode has the step of forming an oxide conductive film composed of crystal of a perovskite structure on a forefront surface of said bottom electrode.

14. The method for manufacturing a semiconductor device according to claim 9, wherein at least one kind selected from a group consisting of La (lanthanum), Si (silicon), Sr (strontium), Ca (calcium), Ba (barium), Na (sodium), K (potassium), Nb (niobium), Ta (tantalum), W (tungsten), Mn (manganese), Fe (iron), Co (cobalt), Ir (iridium), Ru (ruthenium), Cr (chromium) and rare earth elements is used as said impurity.

15. The method for manufacturing a semiconductor device according to claim 9, wherein said ferroelectric film is made thicker than said impurity-doped ferroelectric film.

16. The method for manufacturing a semiconductor device according to claim 9, wherein a thickness of said impurity-doped ferroelectric film is 1 nm to 50 nm.

17. The method for manufacturing a semiconductor device according to claim 9, wherein a film composed of Pb(Zr,Ti)O₃ doped with at least one kind selected from a group consisting of Sr (strontium), Ca (calcium), Nb (niobium), Ir (iridium) and La (lanthanum) is formed as said impurity-doped ferroelectric film.

18. The method for manufacturing a semiconductor device according to claim 17, wherein a doping amount of said impurity is 5 mol % or less for each element.

19. The method for manufacturing a semiconductor device according to claim 9, wherein said annealing is performed under a condition that a flow rate of an oxidizing gas is 25 sccm or less.

20. The method for manufacturing a semiconductor device according to claim 9, wherein said ferroelectric film is formed by an MOCVD method, a sol-gel method or a CSD method.
